(19) United States
(12) Patent Application Publication
(10) Pub. No.: US 2024/0235275 A9
(43) Pub. Date: Jul. 11, 2024

(54) MAGNET ASSEMBLY FOR MOBILE TERMINAL AND WIRELESS CHARGING DEVICE COMBINED THEREWITH

(71) Applicant: NOVATECH CO., LTD., Gyeonggi-do (KR)

(72) Inventors: Seung Jae LEE, Gyeonggi-do (KR); Jae Il NAM, Gyeonggi-do (KR)

(21) Appl. No.: 18/278,468

(22) PCT Filed: Jan. 19, 2023
(86) PCT No.: PCT/KR2023/000961

§ 371 Date: Aug. 23, 2023

(30) Foreign Application Priority Data
Jan. 20, 2022 (KR) 10-2022-0008425

(51) Int. Cl. H02J 50/70; H01F 7/02; H02J 50/10; H05K 9/00

(52) U.S. Cl. CPC H02J 50/70; H01F 7/02; H02J 50/10; H05K 9/0081

(57) ABSTRACT

A magnet assembly for a mobile terminal according to an embodiment includes a base member incorporated into the mobile terminal, and a magnetic member provided on one surface of the base member and including at least one slit formed therein. A wireless charging device for a mobile terminal is capable of being coupled to the magnet assembly by a magnetic force, and the wireless charging device includes a charging module which generates an induced current for charging the mobile terminal, and is coupled to the magnetic member by the magnetic force.

### CROSS REFERENCE TO RELATED APPLICATIONS AND CLAIM OF PRIORITY

This application claims benefit under 35 U.S.C. 119, 120, 121, or 365(c), and is a National Stage entry from International Application No. PCT/KR2023/000961, filed Jan. 19, 2023, which claims priority to the benefit of Korean Patent Application No. 10-2022-0008425 filed in the Korean Intellectual Property Office on Jan. 20, 2022, the entire contents of which are incorporated herein by reference.

### BACKGROUND

### 1. Technical Field

The present invention relates to a magnet assembly for a mobile terminal and a wireless charging device coupled with the magnet assembly by a magnetic force.

### 2. Background Art

In general, a mobile terminal is a terminal that can be freely used while moving regardless of location, and representatively includes a smart phone, a tablet PC, and a personal digital assistant (PDA).

This mobile terminal includes a battery which stores power and a circuit for charging and discharging the battery. In order to charge the batteries of these electronic devices, it is necessary for the batteries to receive a power from an external charger.

Conventionally, the battery is charged with the power using a cable, but it is difficult to arrange the cable and the appearance is not good in this method. In addition, due to recent environmental regulations, development and production of a portless type terminal without input and output terminals are increasing. As a result, development of a wireless charging system using a method of transmitting power wirelessly has been actively conducted due to the above situation. As an example, a wireless charging device capable of being charged by simply placing a smartphone on a charging pad has been developed.

However, in the case of the conventional wireless charging device, it is not easy to use the mobile terminal during wireless charging, and there are problems in that the mobile terminal is separated from the wireless charging device during charging, such that charging may not be performed smoothly and the like.

### SUMMARY

An object of the present invention is to provide a magnet assembly for a mobile terminal that enables the mobile terminal to be wirelessly charged while placing it on a plane or ground, and a wireless charging device coupled with the magnet assembly by a magnetic force.

To achieve the above object, according to an aspect of the present invention, there is provided a magnet assembly for a mobile terminal including: a base member incorporated into the mobile terminal; and a magnetic member provided on one surface of the base member and including at least one slit formed therein.

In addition, the base member may be provided in a circular plate shape having a hollow formed therein.

In addition, the magnet assembly may further include a shielding member which is disposed between the base member and the magnetic member, and shields an effect of a magnetic force generated from the magnetic member on a signal of an E-payment (MST), an NFC, or a wireless charging coil antenna of the mobile terminal.

Further, the shielding member may be provided in the same shape as the magnetic member.

Further, the shielding member may include one selected from iron, silicon and zinc.

Further, the shielding member may be provided so as not to interfere with the E-payment (MST), the NFC, or the wireless charging coil antenna.

Further, the slit formed in the magnetic member may be provided to have a width of at least 1 to 10 mm.

Further, the magnetic member may include a plurality of slice members having slits formed alternately therebetween, and may be provided in a circular plate shape having a hollow formed therein.

Further, the plurality of slits may be arranged at an equal interval in a circumferential direction of the magnetic member.

Furthermore, the magnetic member may be provided as a permanent magnet or a neodymium magnet.

According to another aspect of the present invention, there is provided a wireless charging device for a mobile terminal capable of being coupled to the magnet assembly for a mobile terminal by a magnetic force, the wireless charging device including: a charging module which generates an induced current for charging the mobile terminal, and is coupled to the magnetic member by the magnetic force.

In addition, the charging module may include a magnetic body having the same structure as the magnetic member to improve a coupling force with the mobile terminal.

According to the present invention, by installing the magnet assembly in the mobile terminal, it may be detachably coupled with the wireless charging device provided with the magnetic body by a magnetic force. Accordingly, in this state, it is possible to prevent the mobile terminal from being separated from the wireless charging device during wireless charging, thereby preventing a decrease in wireless charging efficiency due to loose contact during wireless charging.

In addition, by forming a plurality of slits in the magnetic member, it is possible to prevent interference with radio waves of an E-payment (magnetic secure transmission, MST), a near-field communication (NFC), or a wireless charging coil antenna of the mobile terminal due to the magnetic force generated from the magnetic member. Accordingly, it is possible to minimize heat generation while improving the efficiency of the E-payment (MST), the NFC, or the wireless charging coil antenna.

Further, since the charging location of the mobile terminal may be precisely positioned through the magnetic member, wireless charging efficiency may be improved.

Furthermore, since the mobile terminal may be charged while standing on the ground through the wireless charging device, usability thereof may be improved, such as watching a video while performing wireless charging.

### BRIEF DESCRIPTION OF THE DRAWINGS

FIG. 1 is a perspective view of a magnet assembly for a mobile terminal according to an embodiment of the present invention.

FIG. 2 is a front view of the magnet assembly shown in FIG. 1.

FIGS. 3 to 6 are front views of a magnetic member according to another embodiment.

FIG. 7 is a view illustrating an example in which the magnet assembly shown in FIG. 1 is attached to a mobile terminal.

FIG. 8 is a perspective view of a magnet assembly for a mobile terminal according to another embodiment of the present invention.

FIG. 9 is a perspective view of a wireless charging device for a mobile terminal according to an embodiment of the present invention.

FIG. 10 is an exploded perspective view of the wireless charging device shown in FIG. 9.

FIG. 11 is a view illustrating an example in which a mobile terminal having the magnet assembly according to the present invention installed therein and the wireless charging device are coupled by a magnetic force.

### DETAILED DESCRIPTION

Hereinafter, a magnet assembly for a mobile terminal according to a preferred embodiment and a wireless charging device coupled with the magnet assembly will be described in detail with reference to the accompanying drawings. Here, same reference numerals will be denoted to the same configurations, and the publicly known functions and configurations that are judged to be able to make the purport of the present invention unnecessarily obscure will not be repeatedly described in detail. Such embodiments are provided for completely describing the present invention to persons having ordinary knowledge and skills in the related art. Therefore, shapes and sizes of elements in the drawings may be exaggerated for clearer description.

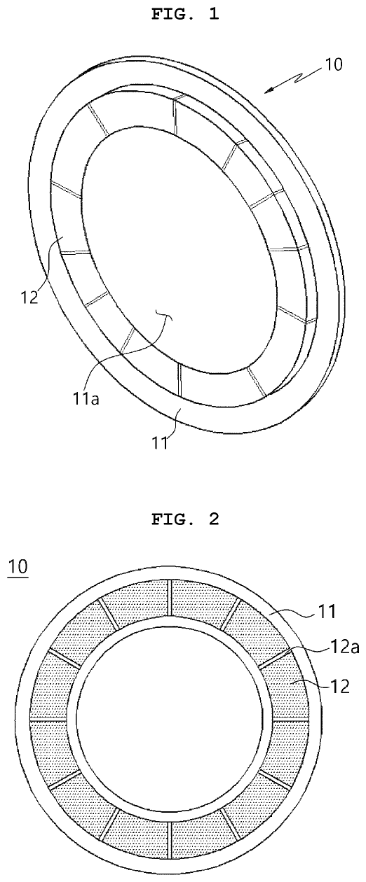

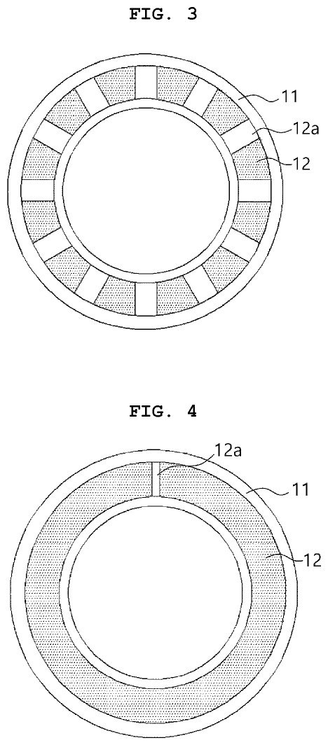

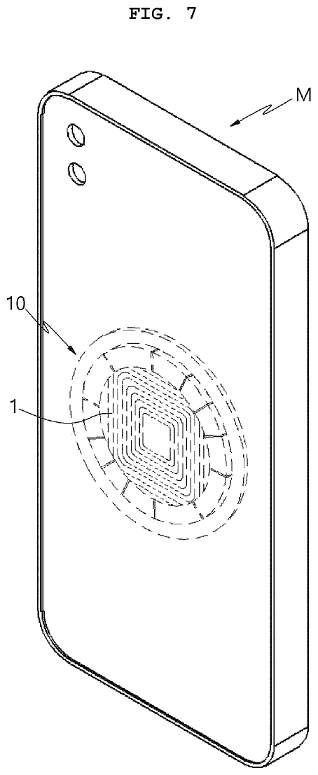

FIG. 1 is a perspective view of a magnet assembly for a mobile terminal according to an embodiment of the present invention, FIG. 2 is a front view of the magnet assembly shown in FIG. 1, FIGS. 3 to 6 are front views of a magnetic member according to another embodiment, and FIG. 7 is a view illustrating an example in which the magnet assembly shown in FIG. 1 is attached to a mobile terminal.

Referring to FIGS. 1 to 7, a magnet assembly 10 for a mobile terminal is installed inside a mobile terminal M, and may include a base member 11 and a magnetic member 12.

The mobile terminal M in the present embodiment may be a smart phone provided with a wireless power reception unit that enables a built-in battery to be charged. Specifically, the mobile terminal M may be a smart phone provided with an antenna module 1 such as an E-payment (MST), an NFC, or a wireless charging coil antenna. However, examples of the mobile terminal M are not limited thereto, and the present invention may be applied to various portable devices such as a tablet PC, a smart watch, a PDA, an earphone and the like.

The base member 11 is intended to support the magnetic member 12 and may be incorporated into the mobile terminal M. For example, the base member 11 may be provided in a circular plate shape having a hollow 11a formed therein, and may be made of a dielectric material such as a plastic film so as not to interfere with signals generated from the E-payment (MST), the NFC, or the wireless charging coil antenna of the mobile terminal M.

The magnetic member 12 is provided on one surface of the base member 11, and may include at least one slit 12a formed therein. For example, the magnetic member 12 may have a diameter formed smaller than that of the base member 11 so that an edge portion thereof does not extend from the edge portion of the base member 11. In addition, when the magnetic member 12 includes a plurality of slits 12a formed therein, these slits may be arranged at an equal interval in a circumferential direction thereof.

The magnetic member 12 may be provided as a permanent magnet or a neodymium magnet. In particular, the neodymium magnets have a strong magnetic force of 25 to 50 MGOe, and are suitable for use as the magnetic member 12 due to their good workability and low price compared to samarium-cobalt magnets or aluminium-nickel-cobalt (AlNiCo) magnets. However, the neodymium magnet rusts easily, such that it is preferable to use by plating the surface thereof with nickel.

As described above, when the mobile terminal M is provided with the magnetic member 12 therein, it is possible to apply a magnetic force to the mobile terminal M. Thereby, the mobile terminal M may be attached to and detached from a device provided with a magnetic body by the magnetic force without a separate attachment tool.

Meanwhile, a smart phone having an antenna module 1 such as an E-payment (MST), an NFC, a wireless charging coil antenna, or the like has been developed and spread in recent years. In this case, when the antenna module 1 and the magnetic member 12 interfere with each other, radio waves of the antenna module 1 are obstructed by the magnetic force generated from the magnetic member 12.

In order to solve this problem related to the radio wave interference, the magnetic member 12 may include a plurality of bodies spaced apart from each other. For example, the magnetic member 12 may include a plurality of slice members having slits 12a formed alternately therebetween, and may be provided in a circular plate shape having a hollow 11a formed therein. That is, by forming the slits 12a in the magnetic member 12, the magnetic field of the magnetic member 12 is dissipated through the slits 12a, thereby reducing an effect of the magnetic field on the antenna module 1 such as an E-payment (MST), an NFC, a wireless charging coil antenna or the like.

The slits 12a formed in the magnetic member 12 may have a variable width as shown in FIG. 3. For example, the slit 12a may be provided to have a width of at least 1 to 10 mm. The reason is that, if the width of the slit 12a is less than 1 mm, it is difficult for the magnetic field of the magnetic member 12 to be dissipated through the slits 12a, which may affect the antenna module, whereas if the width exceeds 10 mm, a strength of the magnetic force may be weakened.

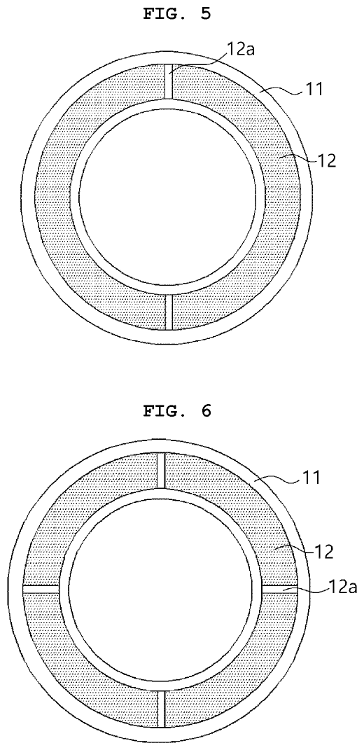

The number of slits 12a formed in the magnetic member 12 is also not limited, and as shown in FIGS. 4 to 6, it is possible to implement in various ways. That is, as shown in FIG. 4, the slit 12a may be formed only in an upper portion of the magnetic member 12, as shown in FIG. 5, the slits 12a may be formed in upper and lower portions, or as shown in FIG. 6, the slits 12a may be formed in the upper and lower portions, as well as left and right portions.

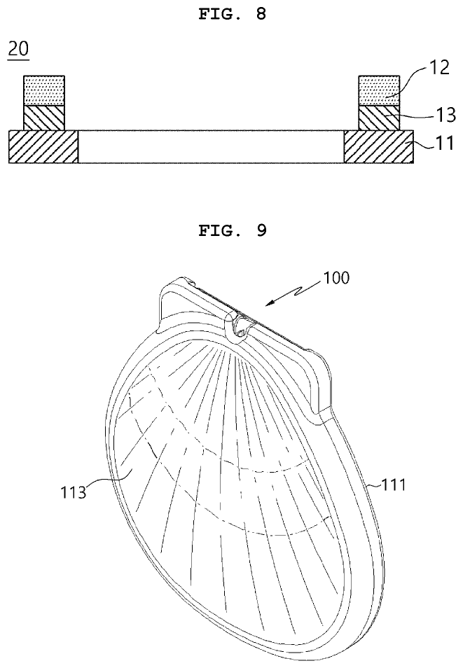

FIG. 8 is a perspective view of a magnet assembly for a mobile terminal according to another embodiment of the present invention.

Referring to FIG. 8, a magnet assembly 20 for a mobile terminal may further include a shielding member 13 which is disposed between the base member 11 and the magnetic member 12, and shields an effect of the magnetic force generated from the magnetic member 12 on a signal of the antenna module 1 including at least one of the E-payment (MST), the NFC, and the wireless charging coil antennas.

For example, the shielding member 13 may have the same shape as the magnetic member 12. That is, the shielding member 13 may also be provided in a circular plate shape having slits formed therein at an interval. This is intended to ensure that the signal from the antenna module 1 is smoothly transmitted between the slits while shielding the magnetic force of the magnetic member 12 by the shielding member 13.

The shielding member 13 may include one selected from iron, silicon and zinc, which are capable of shielding and reflecting the magnetic force while having high magnetic permeability. Accordingly, it is possible to shield the magnetic force generated from the magnetic member 12 from being dissipated toward the antenna module 1 by the shielding member 13, and it is possible to concentrate and strengthen the magnetic force in a direction opposite thereto. The thicker the shielding member 13, the better the shielding effect, but it is preferable to form the shielding member 13 to have a thickness of about 1 to 10 mm in consideration of weight reduction and thickness decrease.

In addition, when the shielding member 13 interferes with the antenna module 1, radio waves of the antenna module 1 may be obstructed, thus it is preferable that the base member 11 is provided so as not to interfere with the antenna module 1 including at least one of the E-payment (MST), the NFC, and the wireless charging coil antennas. For example, by forming the hollow 11a of the base member 11 equal to or larger than the antenna module 1 so that the antenna module 1 is disposed inside the hollow 11a, it is possible to solve the interference between the shielding member 13 and the antenna module 1.

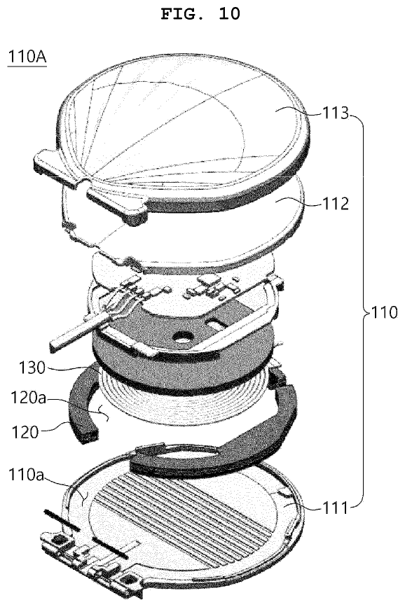

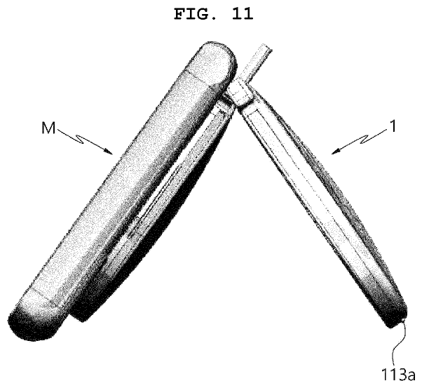

FIG. 9 is a perspective view of a wireless charging device for a mobile terminal according to an embodiment of the present invention, and FIG. 10 is an exploded perspective view of the wireless charging device shown in FIG. 9.

Referring to FIGS. 9 and 10, a wireless charging device 100 for a mobile terminal is capable of being coupled to the above-described magnet assembly 10 for a mobile terminal by the magnetic force, and may include a charging module 110A which generates an induced current for charging the mobile terminal M, and is coupled to the magnetic member 12 by the magnetic force. For example, the charging module 110A may include a magnetic body having the same structure as the magnetic member 12 to improve a coupling force with the mobile terminal.

Specifically, the charging module 110A may include a main body 110, a magnetic body 120, and a transmission coil 130.

The main body 110 has an accommodation space 110a formed therein, and may support the mobile terminal M while being coupled to the mobile terminal M. For example, the main body 110 may include: a base part 111 which accommodates the magnetic body 120 and the transmission coil 130 therein and is coupled to the mobile terminal M by the magnetic force; a cover part 112 which is coupled to one surface of the base part 111 to cover the magnetic body 120 and the transmission coil 130; and a supporting part 113 which is pivotally coupled to the base part 111 to selectively expose the one surface of the base part 111, and supports the mobile terminal M together with the base part 111 when the base part 111 is coupled to the mobile terminal M by the magnetic force.

Accordingly, when the supporting part 113 is pivoted while the base part 111 is attached to one surface of the mobile terminal M through the magnetic body 120, the base part 111 and the supporting part 113 may be formed in an “inverted V” shape. That is, the base part 111 and the supporting part 113 may form a support fixture for supporting the mobile terminal M, and thus the mobile terminal M may be placed on the ground during charging. At this time, in order to improve the convenience of use when pivoting the supporting part 113, the supporting part 113 may further include a grip part 113a protruding to a side opposite to a portion where it is pivotally coupled with the base part 111.

The magnetic body 120 may be disposed in the accommodation space 110a of the main body 110 and coupled to the magnetic member 12 by the magnetic force. For example, the magnetic body 120 may be formed in an arc shape having a predetermined thickness and width, and may have a seating space 120a formed therein by opposite ends disposed to face each other. Specifically, the magnetic body 120 may be formed in a multilayer structure in which N poles and S poles are alternately arranged in horizontal and vertical directions, and may have inner and outer diameters formed with the same size as inner and outer diameters of the magnetic member 12. That is, the magnetic body 120 may be formed to have the same width as the magnetic member 12.

As described above, since the wireless charging device 100 is provided with the magnetic body 120 therein, it may be detachably attached to a rear surface of the mobile terminal M equipped with the magnetic member 12 therein.

The transmission coil 130 may generate an induced current when supplying a current and provide the induced current toward the antenna module 1 of the mobile terminal M. For example, the transmission coil 130 may be wound and disposed in the seating space 120a of the magnetic body 120. Due to this structure, an induced current may be generated on a central portion of the charging module 110A while current flows through the transmission coil 130, and the generated induced current is shielded by the cover part 112 and induced toward the base part 111 to which the mobile terminal M is attached. Due to the formation and induction of such an electromagnetic field, it is possible to perform wireless charging more efficiently.

FIG. 11 is a view illustrating an example in which a mobile terminal having the magnet assembly according to the present invention installed therein and the wireless charging device are coupled by the magnetic force. An example of using the wireless charging device for a mobile terminal according to the present invention will be described below with reference to FIG. 11.

First, the wireless charging device 100 is coupled to the rear surface of the mobile terminal M having the magnetic member 12 installed therein using the magnetic body 120 of the charging module 110A. Then, the wireless charging device 100 is coupled to the magnetic member 12 by the magnetic force, and the mobile terminal M may be wirelessly charged by the induced current generated by the transmission coil 130.

In this state, when pivoting the supporting part 113 in one direction by grasping the grip part 113a, the supporting part 113 is spaced apart from the base part 111. Accordingly, when placing the supporting part 113 on the ground, wireless charging is possible while the mobile terminal M is standing, and thus, there is an advantage in that watching a video, or the like is possible while performing wireless charging.

As described above, by installing the magnet assembly in the mobile terminal M, it may be detachably coupled with the wireless charging device 100 provided with the magnetic body 120 by the magnetic force. Accordingly, in this state, it is possible to prevent the mobile terminal M from being separated from the wireless charging device 100 during wireless charging, thereby preventing a decrease in wireless charging efficiency due to loose contact during wireless charging.

In addition, by forming the plurality of slits 12a in the magnetic member 12, it is possible to prevent interference with radio waves of the E-payment (MST), the NFC, or the wireless charging coil antenna of the mobile terminal M due to the magnetic force generated from the magnetic member 12. Accordingly, it is possible to minimize heat generation while improving the efficiency of the E-payment (MST), the NFC, or the wireless charging coil antenna.

In addition, since the charging location of the mobile terminal M may be precisely positioned through the magnetic member 12, wireless charging efficiency may be improved.

Furthermore, since the mobile terminal M may be charged while standing on the ground through the wireless charging device 100, usability thereof may be improved, such as watching a video while performing wireless charging.

Although the present invention has been described with reference to the embodiments shown in the drawings, these are merely an example. It should be understood by persons having common knowledge in the technical field to which the present invention pertains that various modifications of the embodiments may be made, and such modifications are included in the technical protection scope of the present invention. Accordingly, the real technical protection scope of the present invention is determined by the technical idea of the appended claims.

1. A magnet assembly for a mobile terminal, comprising:
a base member incorporated into the mobile terminal; and
a magnetic member provided on one surface of the base member and including at least one slit formed therein.

2. The magnet assembly of claim 1, wherein the base member is provided in a circular plate shape having a hollow formed therein.

3. The magnet assembly of claim 1, further comprising a shielding member which is disposed between the base member and the magnetic member, and shields an effect of a magnetic force generated from the magnetic member on a signal of an E-payment (MST), an NFC, or a wireless charging coil antenna of the mobile terminal.

4. The magnet assembly of claim 3, wherein the shielding member is provided in the same shape as the magnetic member.

5. The magnet assembly of claim 3, wherein the shielding member includes one selected from iron, silicon and zinc.

6. The magnet assembly of claim 3, wherein the shielding member is provided so as not to interfere with the E-payment (MST), the NFC, or the wireless charging coil antenna.

7. The magnet assembly of claim 1, wherein the slit formed in the magnetic member is provided to have a width of at least 1 to 10 mm.

8. The magnet assembly of claim 1, wherein the magnetic member comprises a plurality of slice members having slits formed alternately therebetween, and is provided in a circular plate shape having a hollow formed therein.

9. The magnet assembly of claim 8, wherein the plurality of slits are arranged at an equal interval in a circumferential direction of the magnetic member.

10. The magnet assembly of claim 1, wherein the magnetic member is provided as a permanent magnet or a neodymium magnet.

11. A wireless charging device for a mobile terminal capable of being coupled to the magnet assembly of claim 1 by a magnetic force, the wireless charging device comprising:
a charging module which generates an induced current for charging the mobile terminal, and is coupled to the magnetic member by the magnetic force.

12. The wireless charging device for a mobile terminal according to claim 11, wherein the charging module comprises a magnetic body having the same structure as the magnetic member to improve a coupling force with the mobile terminal.
